(19) United States
(12) Patent Application Publication
(10) Pub. No.: US 2022/0052012 A1
(43) Pub. Date: Feb. 17, 2022

(54) Compliant Electronic Component Interconnection

(71) Applicant: Paricon Technologies Corporation, Taunton, MA (US)

(72) Inventors: Larre H. Nelson, Attleboro, MA (US); Everett Simons, Taunton, MA (US)

(21) Appl. No.: 17/381,990

(22) Filed: Jul. 21, 2021

Related U.S. Application Data
(60) Provisional application No. 63/057,622, filed on Jul. 28, 2020.

(51) Int. Cl. H01L 23/00

(52) U.S. Cl. CPC H01L 24/29; H01L 24/83; H01L 24/05; H01L 2224/05147; H01L 2224/29355; H01L 2224/29291; H01L 2224/29447; H01L 2224/29439; H01L 2224/83815; H01L 2224/8384; H01L 2224/83203; H01L 2224/29411

(57) ABSTRACT

A connector for coupling an electronic component having an external connector pad to another structure, comprising an anisotropic conductive elastomer or adhesive composite comprising a plurality of separate columns of conductive particles held in an insulating matrix, with a top particle exposed to a surface of the matrix, wherein at least the top particle is coated with a metal that can permanently bond to the connector pad of the electronic component. Also disclosed are a related method, and a related electronic assembly.

### CROSS-REFERENCE TO RELATED APPLICATION

This application claims priority of Provisional Application 63/057,622 filed on Jul. 28, 2020, the disclosure of which is incorporated herein by reference.

### BACKGROUND

This disclosure relates to an electronic component electrical interconnect.

Traditionally, semiconductor chips have been connected to each other and to their interface platforms by gold wires and solder balls. Wire bonding and flip-chip solder ball bonding are used to make more than 1 trillion ICs each year. When the size of the packaged IC footprint is not an issue, then these assembly techniques are fine.

Since the semiconductor market is always looking to pack more functions into a smaller space, there is a growing demand for improved IC packaging density. One example of this is called “3D Stacking.” This is a popular way of packaging very high density semiconductor memory modules for thumb drives or solid-state disks. The die-to-die interconnect methods used in this kind of package are: Tungsten columns (made by deposition or plating), Solder balls, and Copper pillars (copper plating, then small solder balls on top of the copper column).

For many of these interconnect methods, an underfill is needed before or after the solder ball reflows onto the IC pad. This is due to the fragile nature of the balls or the copper pillars, and the mismatches of the thermal coefficient of expansion (TCE) of the materials.

Separable interconnects that use an anisotropic conductive elastomer in which tiny nickel particles are magnetically aligned into columns and held in a compressible silicone membrane to facilitate the flow of current from one surface of the elastomer to the other surface, are known. See, e.g., U.S. Pat. No. 6,854,985.

Traditionally, the columns are compressed between two pads to create a low resistance interconnect that can be release and re-compressed, and cycled thousands of times. Some of these interconnects have a high density of nickel columns per square millimeter (the result of the magnetic flux line density of the manufacturing equipment). Typically, this yields about 10 particle columns per pad. This level of redundancy helps to keep the contact resistance (CRES) as low as 10-20 mΩ per contact pair, and allows a potential vertical signal path through the membrane at any location on the membrane.

The nickel particles in these elastomeric interconnects are typically plated with gold or silver. As a result of the magnetic alignment of the nickel particles, the plating materials, and the elastic characteristics of the silicone, this interconnect method provides a low resistance and low inductance signal path from one surface of the silicone membrane to the other. It is also durable and “springy” so it can be used for repeated testing of electronic devices or for quick connect/disconnect of devices to each other.

### SUMMARY

Aspects and examples are directed to interconnects in which the nickel particles are plated with a metal that can be permanently attached (e.g., by reflow or sintering) to the pads of the electronic component.

All examples and features mentioned below can be combined in any technically possible way.

In one aspect, a method of coupling an electronic component having an external connector pad to another structure includes providing an anisotropic conductive composite comprising a plurality of separate columns of conductive particles held in an insulating matrix, with a top particle exposed to a surface of the matrix, wherein at least the top particle is coated with a metal that can permanently bond to the connector pad of the electronic component, creating an assembly by contacting the anisotropic conductive composite with the electronic component such that the top particle of the anisotropic conductive composite is in contact with the connector pad, and exposing the assembly to a temperature and pressure that are sufficient to either reflow the metal of the top particle of the column of the anisotropic conductive composite, or cause the metal of the top particle of the column of the anisotropic conductive composite to bond to the connector pad by sintering.

Some examples include one of the above and/or below features, or any combination thereof. In an example the metal that can permanently bond to the connector pad of the electronic component comprises solder. In an example the metal that can permanently bond to the connector pad of the electronic component comprises copper or silver.

In another aspect a connector for coupling an electronic component having an external connector pad to another structure includes an anisotropic conductive composite comprising a plurality of separate columns of conductive particles held in an insulating matrix, with a top particle exposed to a surface of the matrix, wherein at least the top particle is coated with a metal that can permanently bond to the connector pad of the electronic component.

Some examples include one of the above and/or below features, or any combination thereof. In an example the metal that can permanently bond to the connector pad of the electronic component comprises solder. In an example the metal that can permanently bond to the connector pad of the electronic component comprises copper or silver. In an example the insulating matrix is an adhesive. In an example the elastomer or composite is flexible. In an example the anisotropic conductive composite is provided in sheets or a reel. In an example the anisotropic conductive composite comprises one or more cutouts. In an example the anisotropic conductive composite is carried by a frame.

In another aspect an electronic assembly includes an electronic component having an external connector pad, and an anisotropic conductive composite comprising a plurality of separate columns of conductive particles held in an insulating matrix, with a top particle exposed to a surface of the matrix, wherein at least the top particle is coated with a metal that can permanently bond to the connector pad of the electronic component, and wherein the metal of the top particle of the column of the anisotropic conductive composite is bonded to the connector pad by reflowing, or the metal of the top particle of the column of the anisotropic conductive composite is bonded to the connector pad by sintering.

Some examples include one of the above and/or below features, or any combination thereof. In an example the metal that can permanently bond to the connector pad of the electronic component comprises solder. In an example the metal that can permanently bond to the connector pad of the electronic component comprises copper or silver. In an example the matrix is an adhesive. In an example the matrix is flexible. In an example the anisotropic conductive elastomer or composite is provided in sheets or a reel. In an example the anisotropic conductive composite comprises one or more cutouts. In an example the anisotropic conductive composite is carried by a frame.

### BRIEF DESCRIPTION OF THE DRAWINGS

Various aspects of at least one example are discussed below with reference to the accompanying figures, which are not intended to be drawn to scale. The figures are included to provide illustration and a further understanding of the various aspects and examples, and are incorporated in and constitute a part of this specification, but are not intended as a definition of the limits of the inventions. In the figures, identical or nearly identical components illustrated in various figures may be represented by a like reference character or numeral. For purposes of clarity, not every component may be labeled in every figure. In the figures:

FIG. 1 is highly enlarged schematic cross-sectional diagram of a compliant electronic component interconnect.

FIG. 2 is highly enlarged schematic cross-sectional diagram of a compliant electronic component interconnect in use electrically connecting two components.

FIG. 3 illustrates an interconnect carried by a frame and with a cutout.

FIG. 4 illustrates a roll of interconnect compliant conductive material.

### DETAILED DESCRIPTION

Examples of the systems, methods, assemblies and apparatuses discussed herein are not limited in application to the details of construction and the arrangement of components set forth in the following description or illustrated in the accompanying drawings. The systems, methods, assemblies and apparatuses are capable of implementation in other examples and of being practiced or of being carried out in various ways. Examples of specific implementations are provided herein for illustrative purposes only and are not intended to be limiting. In particular, functions, components, elements, and features discussed in connection with any one or more examples are not intended to be excluded from a similar role in any other examples.

Examples disclosed herein may be combined with other examples in any manner consistent with at least one of the principles disclosed herein, and references to “an example,” “some examples,” “an alternate example,” “various examples,” “one example” or the like are not necessarily mutually exclusive and are intended to indicate that a particular feature, structure, or characteristic described may be included in at least one example. The appearances of such terms herein are not necessarily all referring to the same example.

Also, the phraseology and terminology used herein is for the purpose of description and should not be regarded as limiting. Any references to examples, components, elements, acts, or functions of the computer program products, systems and methods herein referred to in the singular may also embrace embodiments including a plurality, and any references in plural to any example, component, element, act, or function herein may also embrace examples including only a singularity. Accordingly, references in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

A goal of the present disclosure is to create an interconnect that results in a permanent attachment. In a first example, the nickel particles are plated with solder. The manufacturing equipment and methods used in the traditional manufacture of separable anisotropic conductive composite membranes can be used to manufacture the elastomeric interconnect with solder-plated nickel particles.

The contact pads on integrated circuits and other electronic components are typically made of copper, aluminum, and other metals that are compatible with solder balls and currently use solder balls for connections. The assembly method involves pushing the semiconductor die onto the membrane, engaging the top nickel particle with the IC contact pad, and then raising the temperature to the solder reflow temperature so that the solder plating on the nickel particle reflows and bonds to the IC contact pad. It is expected (but not required) that the solder of all of the nickel particles will flow, thus bonding the entire column of nickel particles together. Typical non-leaded solder will reflow at temperatures <220° C. Special, low temperature solders can also be used with lower reflow temperatures.

The resulting permanent connection will have these characteristics: it will be thin (approximately 50-100 μm), it will have a low CRES per IC pad connection (<20 mΩ), it will have a low inductance per IC pad connection (<0.1 nH), each pad-to-pad interconnection will have a high CCC (Current Carrying Capacity), the compression of the membrane will compensate for IC pad coplanarity tolerances, the materials will be compatible with silicon dies and electronic packaging, the materials will be compatible with environmental regulations, the random columns positions will not require precision alignment between the dies, the membrane supporting the nickel particles will act as an underfill, the membrane/underfill will have a uniform consistency with no voids, the manufacturing equipment currently used to make anisotropic separable conductive elastomer can be used, yielding a low cost.

In a second example of the invention, the nickel particles are plated with copper (or some other metal that can be sintered to the copper (or other material) pads on the ICs). When using magnetically aligned particles with this kind of plating, the die will be pushed against the membrane with about 1 MPa of force and a temperature of about 200° C. With the correct choice of the plated material (which could include materials other than copper that can be sintered to the IC pads), the pressure and the temperature, the top particle in the particle column (copper plated nickel) will be sintered to the surface of the copper pad on the IC, creating a permanent bond. It is expected (but not required) that the sintering conditions will also sinter the particles of the column together.

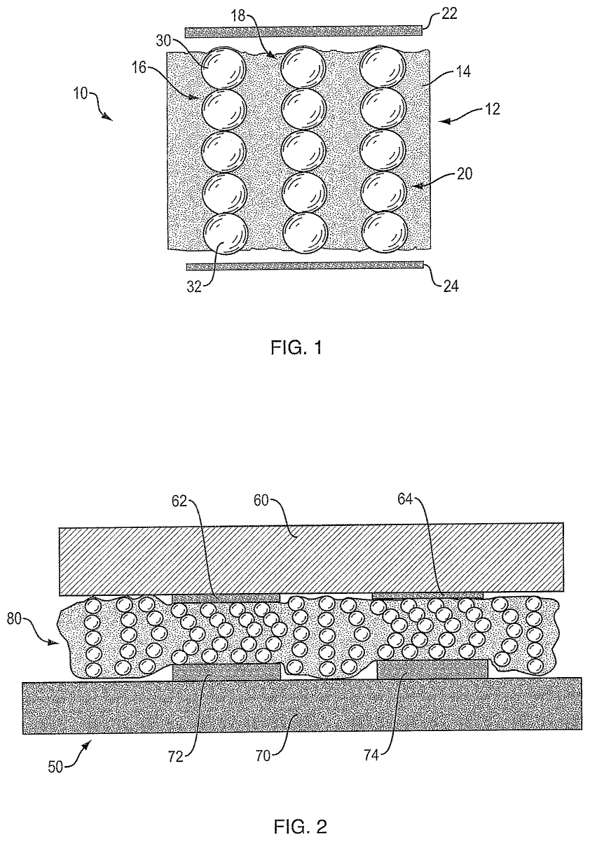

FIG. 1 illustrates assembly 10 that includes anisotropic conductive elastomer or adhesive membrane 12 in the process of being used to electrically interconnect pads 22 and 24; these pads can be of an integrated circuit and another electronic device, or any other electronic devices with external pads that are for electrical connection to the device. Membrane 12 comprises spaced generally vertical columns 16, 18, and 20, each made up of a number of generally aligned particles made from a ferromagnetic material such as nickel, and plated on the outside with a metal that can be reflowed or sintered to pads 22 and 24 held in place in matrix 14. Exemplary outer particles 30 and 32 of column 16 would become permanently affixed to pads 22 and 24, respectively. Note that matrix material 14 is typically compressible, and may be elastomeric and/or may be an adhesive. In some examples the matrix material is flexible. For example, when membrane 12 is used to connect to a flex circuit (e.g., that is made from a polyimide), the matrix can have a similar flexibility, so that assembly 10 is flexible.

A more complete picture of an assembly 50 using anisotropic conductive elastomer or adhesive membrane 80 is depicted in FIG. 2. Electronic devices 60 and 60, with external conductive pads 62, 64, and 72, 74, respectively, are electrically interconnected with membrane 80. FIG. 2 also illustrates that when the membrane is compresses the conductive columns between pads may bow a bit, and the matrix material may extrude slightly to fill some of the space between pads.

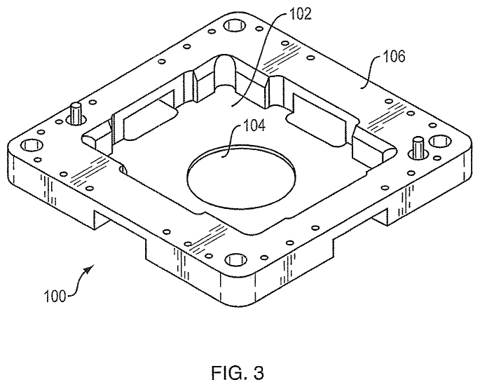

FIG. 3 illustrates sheet 102 of conductive matrix carried by frame 106. Sheet 102 can include one or more cutouts (e.g., cutout 104) that can be included, for example, to accommodate structures of devices being connected. Frame 106 also allows the conductive matrix to be handed via the frame.

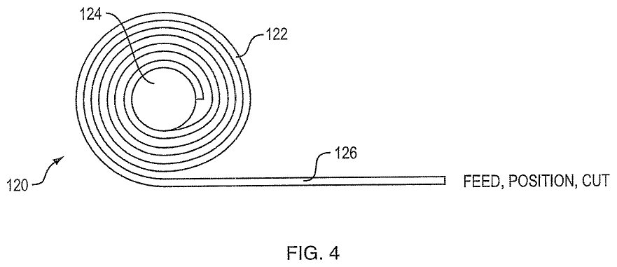

The conductive matrix can be created in thin sheets or rolls, and handled like a b-stage (i.e., not fully cured) material. Such b-stage matrix sheets or rolls can be used in standard electronic component assembly techniques, allowing its use with existing equipment, An exemplary roll 120 of anisotropically conductive matrix material is shown in FIG. 4. Roll 120 is carried on carrier 124 and comprises a long continuous sheet 122 wrapped around carrier 124. End 126 is shown being pulled out or fed, to be positioned cut and other wise handled, as necessary with the components being electrically interconnected with the material. Note that there can be release sheets (not shown) on the top and/or bottom of the roll, to help the material release from the roll.

Having described above several aspects of at least one example, it is to be appreciated various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

What is claimed is:

1. A method of coupling an electronic component having an external connector pad to another structure, comprising:
providing an anisotropic conductive composite comprising a plurality of separate columns of conductive particles held in an insulating matrix, with a top particle exposed to a surface of the matrix, wherein at least the top particle is coated with a metal that can permanently bond to the connector pad of the electronic component;
creating an assembly by contacting the anisotropic conductive composite with the electronic component such that the top particle of the anisotropic conductive composite is in contact with the connector pad; and
exposing the assembly to a temperature and pressure that are sufficient to either reflow the metal of the top particle of the column of the anisotropic conductive composite, or cause the metal of the top particle of the column of the anisotropic conductive composite to bond to the connector pad by sintering.

2. The method of claim 1, wherein the metal that can permanently bond to the connector pad of the electronic component comprises solder.

3. The method of claim 1, wherein the metal that can permanently bond to the connector pad of the electronic component comprises copper or silver.

4. A connector for coupling an electronic component having an external connector pad to another structure, comprising:
an anisotropic conductive composite comprising a plurality of separate columns of conductive particles held in an insulating matrix, with a top particle exposed to a surface of the matrix, wherein at least the top particle is coated with a metal that can permanently bond to the connector pad of the electronic component.

5. The connector of claim 4, wherein the metal that can permanently bond to the connector pad of the electronic component comprises solder.

6. The connector of claim 4, wherein the metal that can permanently bond to the connector pad of the electronic component comprises copper or silver.

7. The connector of claim 4, wherein the composite is an adhesive.

8. The connector of claim 4, wherein the composite is flexible.

9. The connector of claim 4, wherein the anisotropic conductive composite is provided in sheets or a reel.

10. The connector of claim 4, wherein the anisotropic conductive composite comprises one or more cutouts.

11. The connector of claim 4, wherein the anisotropic conductive composite is carried by a frame.

12. An electronic assembly, comprising:
an electronic component having an external connector pad;
an anisotropic conductive composite comprising a plurality of separate columns of conductive particles held in an insulating matrix, with a top particle exposed to a surface of the matrix, wherein at least the top particle is coated with a metal that can permanently bond to the connector pad of the electronic component, and wherein the metal of the top particle of the column of the anisotropic conductive composite is bonded to the connector pad by reflowing, or the metal of the top particle of the column of the anisotropic conductive composite is bonded to the connector pad by sintering.

13. The electronic assembly of claim 12, wherein the metal that can permanently bond to the connector pad of the electronic component comprises solder.

14. The electronic assembly of claim 12, wherein the metal that can permanently bond to the connector pad of the electronic component comprises copper.

15. The electronic assembly of claim 12, wherein the metal that can permanently bond to the connector pad of the electronic component comprises silver.

16. The electronic assembly of claim 12, wherein the composite is an adhesive.

17. The electronic assembly of claim 12, wherein the composite is flexible.

18. The electronic assembly of claim 12, wherein the anisotropic conductive composite is provided in sheets or a reel.

19. The electronic assembly of claim 12, wherein the anisotropic conductive composite comprises one or more cutouts.

20. The electronic assembly of claim 12, wherein the anisotropic conductive composite is carried by a frame.
